(19) United States
(12) Patent Application Publication
(10) Pub. No.: US 2013/0163123 A1
(43) Pub. Date: Jun. 27, 2013

(54) FEED-FORWARD COMPENSATION OF LINEAR-PULSE WIDTH MODULATOR HYBRID POWER SUPPLY

(71) Applicant: Yoshito Otaguro, Kyoto-shi (JP)

(72) Inventor: Yoshito Otaguro, Kyoto-shi (JP)

(21) Appl. No.: 13/336,431

(22) Filed: Dec. 23, 2011

(51) Int. Cl. G11B 5/00; H02K 33/00; H03L 5/00

(52) U.S. Cl. 360/264.7; 327/306; 318/129; G9B/5

(57) ABSTRACT

A circuit device includes a linear driver circuit, a pulse-width modulation driver circuit, an oscillator circuit having an output coupled to the pulse-width modulation circuit, and a feed-forward circuit coupled to the oscillator circuit, the feed-forward circuit being configured to adjust an output of the oscillator circuit so that an output of the PWM circuit substantially matches an output of the linear driver circuit.

### BACKGROUND

A voice coil motor is commonly used as a positioning actuator in the disk read-and-write head of computer hard disk drives. In general, the voice coil motor is driven by one of the following two different drivers depending on the amount of current necessary to drive the motor: (1) a first linear driver when the current applied to the voice coil motor is small and (2) a pulse-width modulation driver when the current applied to the voice coil motor is large. During operation of such hybrid drivers, mode shifts can occur in which the voice coil motor shifts from being driven by the linear driver to the pulse width modulation driver and vice versa. If, however, the output of the linear driver is not properly matched with the output of the pulse width modulation driver during the mode shift, additional time and power can be required to adjust the driver output, leading to poor operating efficiency.

### SUMMARY

The subject matter of this disclosure relates to feed-forward compensation of a linear-pulse width modulator hybrid power supply.

In general, one aspect of the subject matter described in this specification can be embodied in a circuit device that includes a linear driver circuit, a pulse-width modulation driver circuit, an oscillator circuit having an output coupled to the pulse-width modulation circuit, and a feed-forward circuit coupled to the oscillator circuit, the feed-forward circuit being configured to adjust an output of the oscillator circuit so that an output of the pulse-width modulation circuit substantially matches an output of the linear driver circuit.

The circuit device can include one or more of the following features. For example, in some implementations, the feed-forward circuit is configured to adjust the output of the oscillator circuit so that the output of the pulse-width modulation driver circuit matches the output of the linear driver circuit when a power source voltage deviates from a predetermined power source voltage.

In some implementations, the feed-forward circuit is configured to set both maximum and minimum amplitudes of an output of the oscillator circuit. The feed-forward circuit can be configured to set the maximum and minimum amplitudes based on a power source voltage. The feed-forward circuit can be configured to set a difference between the maximum and minimum amplitudes approximately equal to a ratio of a power source voltage to a gain of the linear driver circuit.

In some implementations, the feed-forward circuit includes multiple operational amplifiers. An output of a first operational amplifier of the feed-forward circuit can be coupled to a positive input of a second operational amplifier of the feed-forward circuit and to a positive input of a third operational amplifier of the feed-forward circuit. An output of the second operational amplifier of the feed-forward circuit can be coupled to the oscillator circuit to set a maximum output voltage of the oscillator circuit. An output of the third operational amplifier of the feed-forward circuit can be coupled to the oscillator circuit to set a minimum output voltage of the oscillator circuit.

In various implementations, the circuit device further includes a voice coil motor, in which an output of each of the linear driver circuit and the pulse-width modulation driver circuit is coupled to voice coil motor through a switch. The circuit device can further include an error detection circuit to detect a change in current in the voice coil motor, the error detection circuit being coupled to the pulse-width modulation driver circuit and to the linear driver circuit. The linear driver circuit can include first and second linear amplifiers, the output of the error detection circuit being coupled to an input of each linear amplifier. The pulse-width modulation driver circuit can include first and second operational amplifiers, the output of the error detection circuit being coupled to a positive input of the first operation amplifier and to a negative input of the second operation amplifier. The output of the oscillator circuit can be coupled to a negative input of the first operational amplifier and to a positive input of the second operational amplifier.

Another aspect of the subject matter described in this specification can be embodied in a method of adjusting a gain of a pulse-width modulation driver circuit, in which the method includes modifying, using feed-forward circuitry, an output of an oscillator circuit coupled to the pulse-width modulation driver circuit so that the gain of the pulse-width modulation driver circuit substantially matches a gain of a linear driver circuit.

Modifying the output of the oscillator circuit can include changing maximum and minimum output amplitudes of the oscillator circuit. Changing the maximum and minimum output amplitudes of the oscillator circuit can be based on a power source voltage coupled to the feed-forward circuitry. Modifying the output of the oscillator circuit can include adjusting a difference between maximum and minimum output amplitudes of the oscillator circuit. Adjusting the difference between the maximum and minimum output amplitudes can include setting the difference equal to a ratio of a power source voltage to the gain of the linear driver circuit.

In some implementations, the output of the oscillator circuit is coupled to a negative input of a first operational amplifier of the pulse-width modulation driver circuit and to a positive input of a second operational amplifier of the pulse-width modulation driver circuit. The method can further include coupling an output of an error detection circuit to a positive input of the first operational amplifier and to a negative input of the second operational amplifier. The method can further include coupling the output of the error detection circuit to an input of the linear driver circuit.

Another aspect of the subject matter described in this specification can be embodied in a method of driving a voice coil motor, in which the method includes driving the voice coil motor with a linear driver circuit over a first operating range, driving the voice coil motor with a pulse width modulation driver circuit over a second operating range, and modifying, using feed-forward circuitry, an output of an oscillator circuit coupled to the pulse-width modulation driver circuit so that a gain of the pulse-width modulation driver circuit matches a gain of the linear driver circuit.

Another aspect of the subject matter described in this specification can be embodied in a hard disk drive that includes a voice coil motor, a linear driver circuit, a pulse-width modulation driver circuit, in which an output of each of the linear driver circuit and the pulse-width modulation driver circuit is coupled to the voice coil motor through a switch, an oscillator circuit having an output coupled to the pulse-width modulation driver circuit, and a feed-forward circuit coupled to the oscillator circuit, the feed-forward circuit being operable to adjust an output of the oscillator circuit so that a gain of the pulse-width modulation driver circuit substantially matches a gain of the linear driver circuit.

Another aspect of the subject matter described in this specification can be embodied in a device that includes a linear driver circuit, a pulse-width modulation driver circuit, an oscillator circuit having an output coupled to the pulse-width modulation driver circuit, and a feed-forward circuit coupled to the oscillator circuit, the feed-forward circuit being operable to adjust an output of the oscillator circuit so that output currents of the linear driver circuit and the pulse-width modulation driver circuit become the same when the same input voltages are provided to the linear driver circuit and the pulse-width modulation driver circuit.

The different aspects of the subject matter can include various advantages. For example, in some implementations, adjusting the output of a pulse-width modulation driver can be used to match the output of a linear driver such that reductions in amplifier circuit operating efficiencies due to gain mismatch between drivers are reduced or eliminated. In addition, by using a feed-forward circuit to adjust the output of a pulse-width modulation driver, further inefficiencies due to delays in correcting driver output can be reduced.

Other potential aspects, features and advantages will be apparent from the description, the drawings, and the claims.

### BRIEF DESCRIPTION OF THE DRAWINGS

FIG. 1 is a schematic of an amplifier circuit for a voice coil motor.

FIG. 2 is a plot of example gain curves for a linear driver circuit at different power supply voltages.

FIG. 3 is a plot of example gain curves for a pulse-width modulation driver circuit at different power supply voltages.

FIG. 4 is a schematic of an example amplifier circuit that utilizes a feed-forward circuit to compensate for variations in a power supply voltage.

FIG. 5 is a schematic of an example feed-forward circuit.

FIG. 6A is a plot of a triangle wave signal produced by an oscillator circuit.

FIG. 6B is a plot of a voltage output produced by a first pulse-width modulation amplifier and a second pulse-width modulation amplifier for the triangle wave signal of FIG. 6A.

FIG. 7A is a plot of a triangle wave signal produced by an oscillator circuit.

FIG. 7B is a plot of a voltage output produced by a first pulse-width modulation amplifier and a second pulse-width modulation amplifier for the triangle wave signal of FIG. 7A.

### DETAILED DESCRIPTION

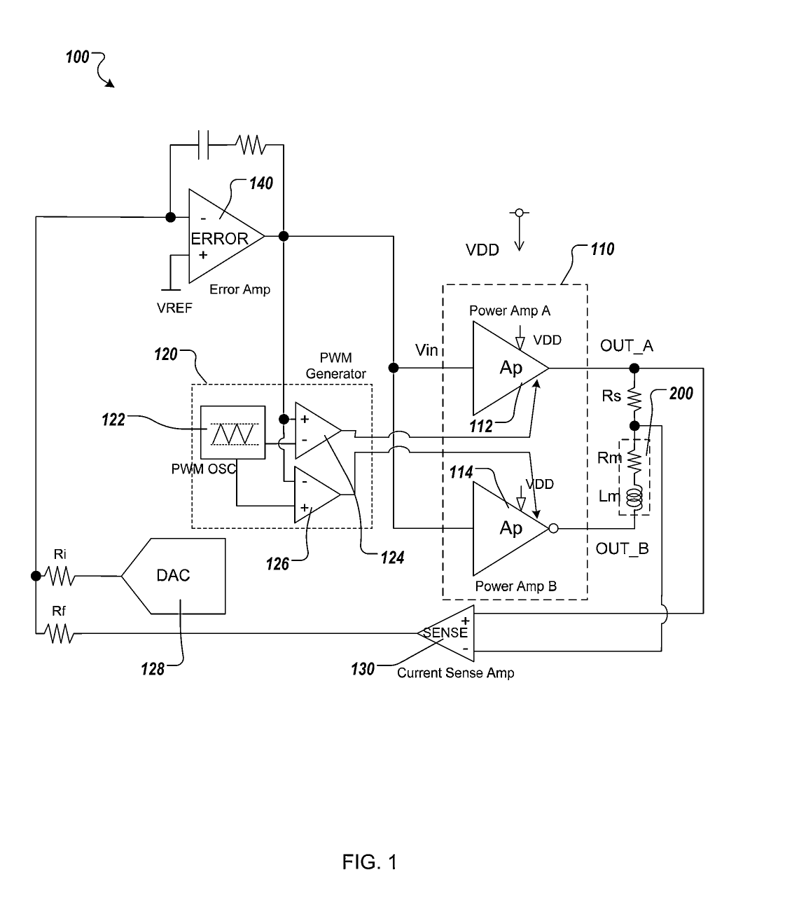

FIG. 1 is a schematic of an amplifier circuit 100 for a voice coil motor (VCM) 200. The amplifier circuit 100 includes two drivers for supplying different levels of current to the VCM 200: a linear driver circuit 110 and a pulse-width modulation (PWM) driver circuit 120. The linear driver 110 includes a first power amplifier 112 and a second power amplifier 114. The PWM driver 120 includes a PWM oscillator circuit 122, a first PWM amplifier 124, and a second PWM amplifier 126. For the PWM driver 120, the output of the PWM oscillator circuit 122 is coupled to a negative input of the first PWM amplifier 124 and to a positive input of the second PWM amplifier 126. The PWM oscillator circuit 122 can include any suitable oscillator circuit such as, for example, a triangle wave oscillator or a saw-tooth oscillator. Both the PWM driver 120 and the linear driver 110 are powered by a supply voltage V_{DD}.

The linear driver 110 and PWM driver 120 are arranged such that either the output of the first power amplifier 112 or the output of the first PWM amplifier 124 is coupled to the VCM 200 at a first node (“OUT_A”). For example, in some implementations, the output of the first power amplifier 112 and the first PWM amplifier 124 are coupled to the first node through a switch. Similarly, the output of the second power amplifier 114 and the second PWM amplifier 126 also are coupled to the VCM 200 at a second node (“OUT_B”).

The amplifier circuit 100 also includes a current sensing amplifier 130 coupled to a series resistor Rₛ that is in series with the VCM 200. The current sensing amplifier 130 is operable to detect the current flowing through the VCM 200 based on the voltage measured across the series resistor Rₛ. The output of the current sensing amplifier 130 is coupled through a feedback resistor R_{f} to a negative input of error amplifier 140. The positive input of error amplifier 140 is coupled to a reference voltage V_{Ref}.

A digital-to-analog converter (DAC) 128 is electrically coupled through resistor Rᵢ to the negative input of the error amplifier 140. The DAC 128 is operable to alter the voltage applied to the error amplifier 140 so that appropriate changes in current to the motor can be obtained. For example, during periods when a change in torque provided by the motor requires a corresponding change in current to the motor, the DAC 128 is operable to adjust the voltage at the negative of the error amplifier 140, as appropriate.

The output of error amplifier 140 is coupled to an input of the PWM driver 120 and to an input of the linear driver 110. In particular, the output of error amplifier 140 is provided as an input voltage Vᵢₙ both to the positive input of the first PWM amplifier 124 and to the negative input of the second PWM amplifier 126. The VCM 200 is represented in the example of FIG. 1 by a motor resistor R_{M} and a motor inductor L_{M} in series.

During operation of the amplifier circuit 100, the linear driver 110 is used to provide current to the VCM 200 over a first range, whereas the PWM driver 120 is used to provide current to the VCM 200 over a second range. The absolute value of the first range of current is smaller than the absolute value of the second range of current. For example, the linear driver 110 can be configured to drive the VCM 200 between 0.5 A and −0.5 A. The PWM driver 120, on the other hand, can be configured to drive the VCM 200 over a range corresponding to larger amount of current, such as currents greater than 0.5 A and less than −0.5 A. The larger current levels may be required, for example, when a disk read-and-write head in a hard disk drive coupled to the VCM 200 moves at high speeds suddenly. Thus, when the current required to drive the VCM 200 is within the first range of current, the linear driver 110 drives the VCM 200. When the magnitude of the current level required to drive the VCM 200 increases from the first range into the second range of current, the circuit 100 switches driving operation to the PWM driver 120.

When the amplifier circuit 100 operates in the second range of current, the PWM driver 120 drives the VCM 200 by outputting a pulse train signal (e.g., a series of square pulses). The average value of voltage (or current) fed to the VCM load depends on the duty cycle and amplitude of the pulse train signal. That is, as the duty cycle of the PWM signal increases from 0 to 100%, the average voltage (or current) supplied by the PWM driver also increases. The duty cycle of the PWM driver output can be controlled by adjusting the value of the reference voltage supplied to each PWM amplifier 124, 126.

In some implementations, the power supply voltage V_{DD} is under a state of burden (e.g., as a result of a change in the current required to drive the VCM 200). When this occurs, the power supply voltage V_{DD} deviates either above or below a nominal value. Such changes in supply voltage typically do not alter the operation of the linear driver 110, which has a constant linear gain curve. In contrast, the slope of the gain curve for the PWM driver 120 typically decreases when the supply voltage falls below the nominal value or increases when the supply voltage rises above the nominal value. As a result, the gain curves of the linear driver 110 and the PWM driver 120 may not be properly matched when there are fluctuations in supply voltage. Such mismatch in gain curves can lead to inefficiencies in power consumption and operating speed of the amplifier circuit 100 particularly when the amplifier circuit 100 switches driver operation from the linear driver 110 to the PWM driver 120 or vice-versa.

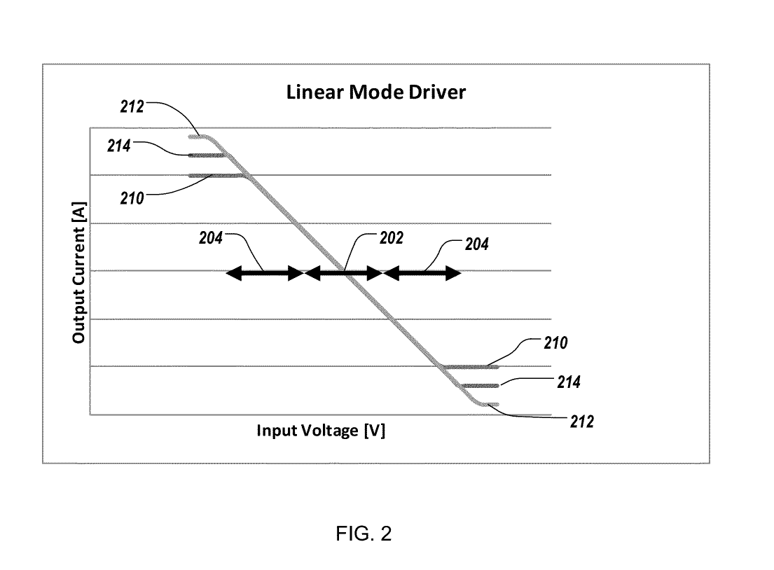

For instance, FIG. 2 is a plot of example gain curves for a linear driver circuit at different power supply voltages. In particular, FIG. 2 shows output current from the linear driver circuit 110, as measured through resistor Rₛ, versus the input voltage Vᵢₙ supplied by the error amplifier 140. The plot include includes three gain curves: a first gain curve 210 when a power supply voltage is lower than a nominal power supply voltage; a second gain curve 212 when a power supply voltage is above the nominal power supply voltage; and a third gain curve 214 when a power supply voltage is equal to the nominal value. As can be seen in the plot, the three gain curves have the same slope and overlap one another over a substantial range of input voltages. The range 202 corresponds to the input voltages over which the linear driver 110 drives the VCM 200. The range 204 corresponds to the input voltages over which the PWM driver 120 drives the VCM 200. The ranges 202, 204 shown in FIG. 2 are examples of applicable ranges and do not limit the possible ranges over which the circuit 100 can operate.

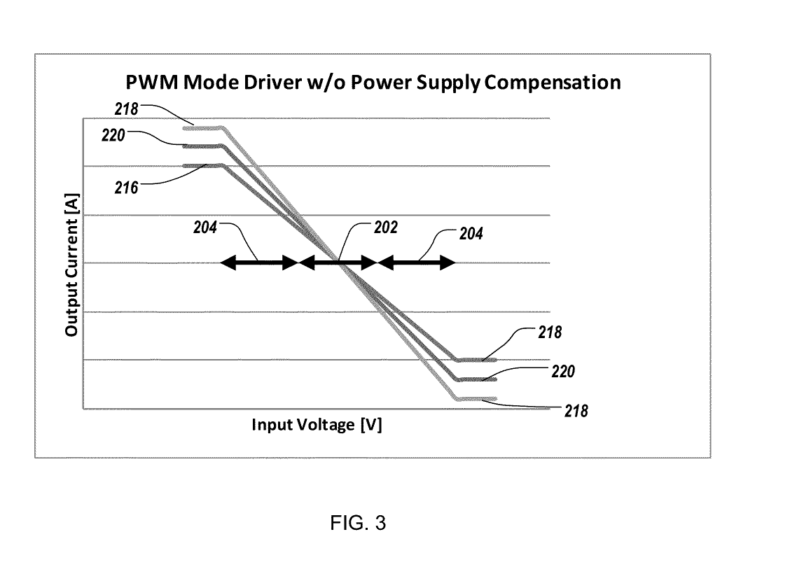

FIG. 3 is a plot of example gain curves for a PWM driver circuit at different power supply voltages. In particular, FIG. 3 shows output current from the PWM driver circuit 120, as measured through resistor Rₛ, versus the input voltage Vᵢₙ supplied by the error amplifier 140. The plot include includes three gain curves: a first gain curve 216 when a power supply voltage is lower than a nominal power supply voltage; a second gain curve 218 when a power supply voltage is above the nominal power supply voltage; and a third gain curve 220 when a power supply voltage is equal to the nominal value. In contrast to the gain curves of the linear driver circuit 110 shown in FIG. 2, the gain curves for the PWM driver 120 have different respective slopes depending on the power supply voltage. For example, the slope of the first gain curve 216 decreases when the power supply voltage is below the nominal power supply value whereas the slope of the second gain curve 218 increases when the power supply voltage is above the nominal power supply value. When the amplifier circuit 100 switches between driving the VCM 200 with the PWM driver 120 (over range 204) to driving the VCM 200 with the linear driver 110 (over range 202) or vice-versa, a gain mismatch occurs for power supply voltages above or below the nominal value. If such gain mismatch is not addressed, it can lead to a reduction in amplifier circuit operating efficiency.

The change in slope of the PWM driver gain curves occurs when the supply voltage V_{DD} fluctuates. That is, when the power supply voltage V_{DD} changes under a state of burden, the slope of the PWM driver gain curve also changes. To correct for the variation in PWM driver gain curve, a feed-forward circuit can be added to the amplifier circuit 100. Because the variation in the PWM driver circuit gain curve is based on changes in the supply voltage, the feed-forward circuit is configured to detect a change in the power supply voltage and automatically adjust the output of the PWM driver so that the output matches the gain curve of the linear driver.

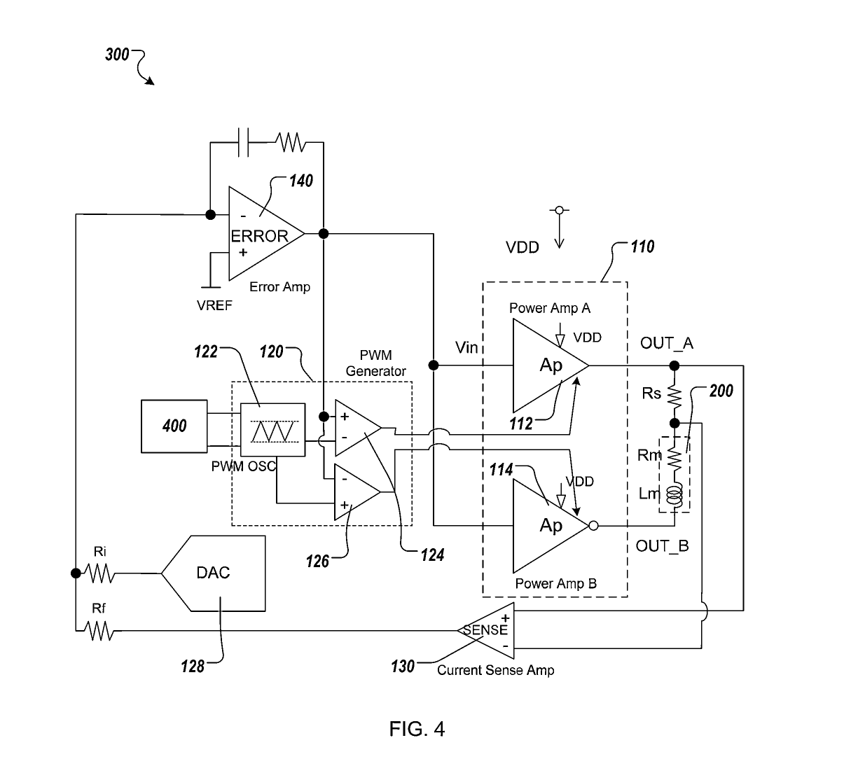

FIG. 4 is a schematic of an example amplifier circuit 300 that utilizes a feed-forward circuit 400 to compensate for variations in a power supply voltage. The feed-forward circuit 400 is operable to cause the output of the PWM driver 120 to match the output of the linear driver 110 for a given input voltage Vᵢₙ (i.e., the voltage output by the error amplifier 140). As shown in FIG. 4, the feed-forward circuit 400 is coupled to the PWM oscillator circuit 122.

During operation of the amplifier circuit 300, the feed-forward circuit 400 adjusts, based on the power supply voltage, the difference between maximum and minimum values of a triangle waveform signal produced by the oscillator circuit 122. By adjusting the difference between the maximum and minimum values of the waveform signal, it is possible to cause the current output of the PWM driver 120 to match the current output supplied by the linear driver 110, regardless of the variation in power supply voltage.

The difference between the maximum and minimum values of the triangle waveform signal that cause the output of the PWM driver 120 to match the output of the linear driver 110 can be determined from the gain equations for each driver. The current output, Iₒᵤₜ, of the linear driver 110 is given by

$${I}_{OUT} • 2 {A}_{Lin} ( \frac{{V}_{in} - {V}_{ref}}{{R}_{M}} ) , \qquad ( 1 )$$

where A_{Lin} is the gain of each power amplifier in the linear driver 110, R_{M} corresponds to the value of the VCM resistor, and V_{Ref} is a reference voltage supplied to each power amplifier. The current output of the PWM driver 120 is given by

I_{PWM}□PWM_{Duty}(V_{DD}/R_{M}), (2)

where

PWM_{Duty}=2Iᵢₙ/(V_{H}−V_{L}). (3)

V_{H} and V_{L} correspond, respectively, to the maximum output voltage and minimum output voltage supplied by the oscillator circuit 122. From equations (2) and (3), the gain of one of the amplifiers of the PWM driver 120 is given by

A_{PWM}□2V_{DD}/2(V_{H}−V_{L}). (4)

From equation (4), the difference between the maximum and minimum output of the oscillator circuit 122 is

(V_{H}−V_{L})=2V_{DD}/2A_{PWM}. (5)

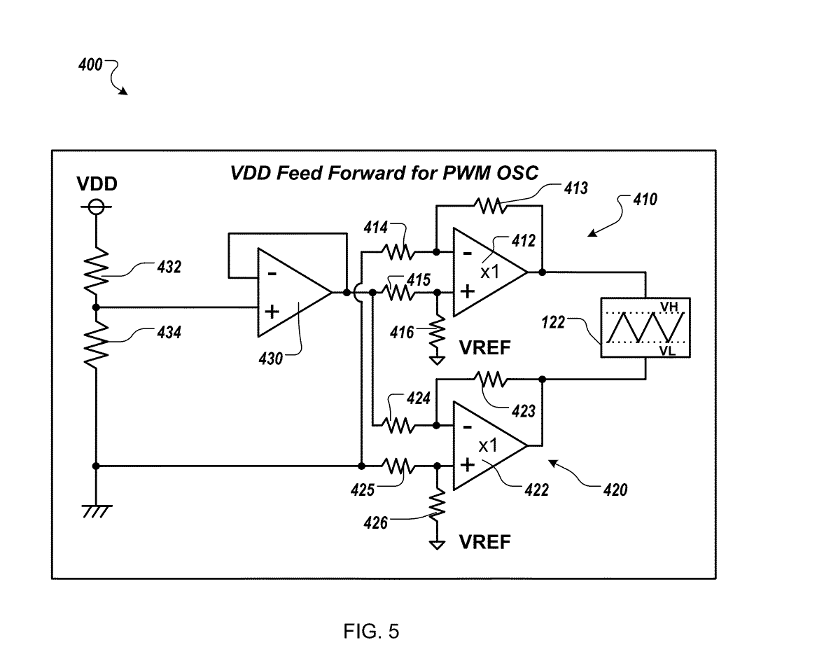

FIG. 5 is a schematic of an example feed-forward circuit 400 that is configured to provide the voltage difference specified in equation (5). The feed-forward circuit 400 includes a first differential amplifier 410, a second differential amplifier 420, and a voltage follower 430. The first differential amplifier 410 includes an operational amplifier 412 with a gain of one, as well as resistors 413-416. The second differential amplifier 420 includes an operational amplifier 422 with a gain of one, as well as resistors 423-426. The voltage follower 430 also includes an operational amplifier with a gain of one. The reference voltage V_{REF} is set to a predetermined value that depends on the specified voltage difference V_{H}−V_{L}.

As shown in FIG. 5, the voltage received at the positive input of the voltage follower 430 is determined by the voltage divider formed by resistors 432 and 434 and the power supply voltage coupled to resistor 432. The output of the voltage follower 430 then is passed to both of the differential amplifiers 410, 420. The output of the first differential amplifier 410 is coupled to an input of the oscillator 122 that sets the maximum oscillator output voltage V_{H} whereas the output of differential amplifier 420 is coupled to an input of oscillator 122 that sets the minimum oscillator output voltage V_{L}.

Using the example resistor values set forth in Table I below, as well as a reference voltage V_{Ref} of 0.75 V, Table II gives examples of the voltages that can be obtained at the different nodes shown in the circuit of FIG. 5 for different power supply voltages (i.e., V_{DD}=10 V and V_{DD}=14 V).

TABLE I

| Resistor | Value |
|---|---|
| 432 | 1900K Ω |
| 434 | 100K Ω |
| 413 | 50K Ω |
| 414 | 50K Ω |
| 415 | 50K Ω |
| 416 | 50K Ω |
| 423 | 50K Ω |
| 424 | 50K Ω |
| 425 | 50K Ω |
| 426 | 50K Ω |

TABLE II

| Node | Node Voltage for V_{DD} = 10 V | Node Voltage for V_{DD} = 14 V |
|---|---|---|
| A | 0.5 V | 0.7 V |
| B | 0.625 V | 0.725 V |
| C | 0.625 V | 0.725 V |
| D | 0.375 V | 0.375 V |
| E | 0.375 V | 0.375 V |
| F (V_{H}) | 1.25 V | 1.45 V |
| G (V_{L}) | 0.25 V | 0.05 V |
| H (V_{Ref}) | 0.75 V | 0.75 V |
| I | 0.5 V | 0.7 V |

Thus, as shown in TABLE II, the feed-forward circuit 400 is capable of changing the maximum output voltage of the oscillator circuit 122 from 1.25 V (when V_{DD} equals 10 V) to 1.45 V (when V_{DD} equals 14 V). Similarly, the feed-forward circuit can change the minimum output voltage of the oscillator circuit 122 from 0.25 V (when V_{DD} equals 10 V) to 0.05 V (when V_{DD} equals 14 V). Feed-forward circuit 400 is not limited to the example resistor values and reference voltage specified in Tables I and II. Rather, any suitable resistor values and reference voltages that enable the feed-forward circuit 400 to obtain a specified between voltage difference between V_{H} and V_{L} can be used.

### Example 1

### Operation of Amplifier Circuit With VDD Low

An example operation of the amplifier circuit 300 in which the power supply voltage V_{DD} is low (e.g., 10 V) relative to a nominal power supply value (e.g., 12 V), will now be described. For the present example, it is assumed that each of the power amplifiers 112, 114 has a gain A_{Lin} approximately equal to ten, the reference voltage V_{Ref} supplied to the power amplifiers is about 0.75 V, and the VCM resistor R_{M} has a value of about 10Ω. In addition, each of the power amplifiers 112, 114 has a neutral operating voltage equal to one-half the power supply voltage V_{DD}. That is, when the difference between Vᵢₙ and V_{Ref} at the input to either power amplifier is zero, each amplifier has an output voltage approximately equal to V_{DD}/2.

Assuming, for the purposes of the present example, that the current, Iₒᵤₜ, required to drive the VCM 200 is about 1.0 A, equation (1) can be used to solve for the voltage V_{II}, applied to the linear driver 110 from the error amplifier 140. That is, Vᵢₙ=(R_{M}*I_{OUT})/(2A_{Lin})+V_{Ref}=1.25 V. Equation (1) also can be rearranged to determine the voltage output of the first power amplifier 112. In particular, the power amplifier voltage output for amplifier 112 is given by:

V_{OUT1}=(Vᵢₙ−V_{Ref})A_{Lin}+V_{DD}/2=5 V+5 V=10 V (6).

In contrast, the polarities of Vᵢₙ and V_{Ref} are reversed for the second power amplifier 114. Thus, the voltage output for amplifier 114 is given by:

V_{OUT2}=(V_{Ref}−Vᵢₙ)A_{Lin}+VDD/2=−5 V+5 V=0 V (7).

The difference between V_{OUT1} and V_{OUT2} gives the overall voltage (10 V) supplied by the linear driver 110 across the VCM 200.

When the amplifier circuit 300 switches from the linear driver 110 to the PWM driver 120 at low V_{DD}, the feed-forward circuit 400 is operable to modify the output of the PWM driver 120 so that the gain curves for both the linear driver 110 and PWM driver 120 match.

In particular, the feed-forward circuit 400 automatically adjusts, based on the supply voltage V_{DD}, the maximum and minimum output voltages (V_{H}, V_{L}) of the triangle wave signal produced by oscillator circuit 122. The values of V_{H} and V_{L}, in turn, establish the duty cycle of the pulse train signal output by the PWM driver 120. In the present example, the feed-forward circuit 400 automatically sets the maximum voltage V_{H} to 1.25 V and sets the minimum voltage V_{L} to 0.25 V based on the supply voltage (V_{DD}=10 V), resulting in a 100% duty cycle for the pulse train signal produced by the first PWM amplifier 124 and 0% duty cycle for the second PWM amplifier 126.

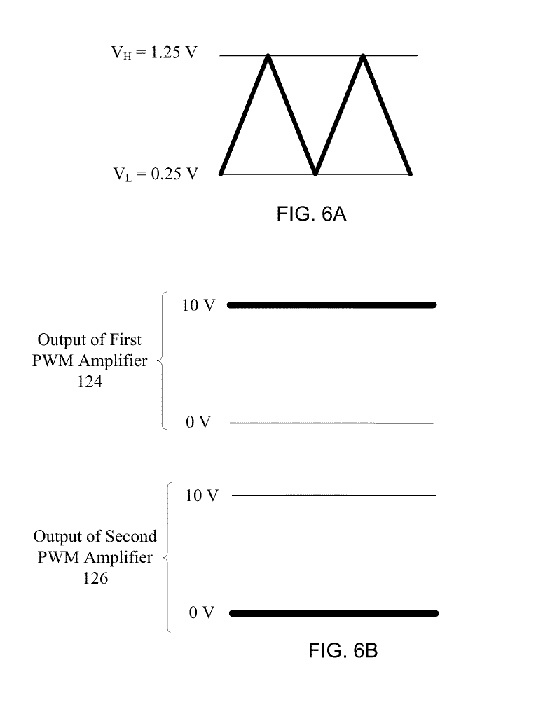

For example, FIG. 6A is a plot of a corresponding triangle wave signal produced by the oscillator circuit 122. FIG. 6B is a plot of the voltage output produced by the first PWM amplifier 124 and the second PWM amplifier 126 for the triangle wave signal of FIGS. 6A and Vᵢₙ=1.25 V. As shown in FIG. 6B, the voltage output of the first PWM amplifier 124 goes high to 10 V whereas the voltage output of the second PWM amplifier 126 stays low at 0 V. Because the output of PWM driver 120 corresponds to the difference between the average of the first PWM amplifier output and the average of the second PWM amplifier output, the total output voltage of the PWM driver 120 is 10 V and thus matches the voltage (and current) produced by the linear driver 110.

When the operating current of the VCM 200 changes, the error amplifier 140 automatically adjusts Vᵢₙ and thus changes the duty cycle of the pulse train signals produced by the amplifiers of PWM driver 120. For example, Table III below shows the duty cycles for the first PWM amplifier 124 and for the second PWM amplifier 126 at different currents through the VCM 200.

TABLE III

| | | | | | | | | | | | |
|---|---|---|---|---|---|---|---|---|---|---|---|
| DUTY First | 100% | 90% | 80% | 70% | 60% | 50% | 40% | 30% | 20% | 10% | 0 |
| Amplifier 124 | | | | | | | | | | | |
| DUTY Second | 0 | 10% | 20% | 30% | 40% | 50% | 60% | 70% | 80% | 90% | 100% |
| Amplifier 126 | | | | | | | | | | | |
| Output of | 1.25 V | 1.15 V | 1.05 V | 0.95 V | 0.85 V | 0.75 V | 0.65 V | 0.55 V | 0.45 V | 0.35 V | 0.25 V |
| Error Amp 140 | | | | | | | | | | | |
| I_{OUT} | 1.0 A | 0.8 A | 0.6 A | 0.4 A | 0.2 A | 0 A | −0.2 A | −0.4 A | −0.6 A | −0.8 A | −1.0 A |

### Example 2

### Operation of Amplifier Circuit With VDD High

An example operation of the amplifier circuit 300 in which the power supply voltage V_{DD} is high (e.g., 14 V) relative to a nominal power supply value (e.g., 12 V), will now be described. For the present example, it is again assumed that each of the power amplifiers 112, 114 has a gain A_{Lin} approximately equal to ten, the reference voltage V_{Ref} supplied to the power amplifiers is about 0.75 V, and the VCM resistor R_{M} has a value of about 10Ω. The neutral operating voltage for each of the power amplifiers 112, 114 is V_{DD}/2=7 V.

Assuming, for the purposes of the present example, that the current, Iₒᵤₜ, required to drive the VCM 200 is about 1.0 A, the voltage Vᵢₙ is determined using equation (1) to be 1.25 V. The power amplifier voltage output for amplifier 112 is given by:

V_{OUT1}=(Vᵢₙ−V_{Ref})A_{Lin}+V_{DD}/2=5 V+7 V=12 V (8).

In contrast, the polarities of Vᵢₙ and V_{Ref} are reversed for the second power amplifier 114. Thus, the voltage output for amplifier 114 is given by:

V_{OUT2}=(V_{Ref}−Vᵢₙ)A_{Lin}+VDD/2=−5 V+7 V=2 V (9).

The difference between V_{OUT1} and V_{OUT2} gives the overall voltage (10 V) supplied by the linear driver 110 across the VCM 200.

When the amplifier circuit 300 switches from the linear driver 110 to the PWM driver 120 at high V_{DD}, the feed-forward circuit 400 is operable to modify the output of the PWM driver 120 so that the gain curves for both the linear driver 110 and PWM driver 120 match.

In particular, the feed-forward circuit 400 automatically adjusts, based on the supply voltage V_{DD}, the maximum and minimum output voltages (V_{H}, V_{L}) of the triangle wave signal produced by oscillator circuit 122. The values of V_{H} and V_{L}, in turn, establish the duty cycle of the pulse train signal output by the PWM driver 120. In the present example, the feed-forward circuit 400 automatically sets the maximum voltage V_{H} to 1.45 V and sets the minimum voltage V_{L} to 0.05 V based on the supply voltage (V_{DD}=14 V), resulting in an approximately 85.7% duty cycle for the pulse train signal produced by the first PWM amplifier 124 and approximately 14.2% duty cycle for the second PWM amplifier 126.

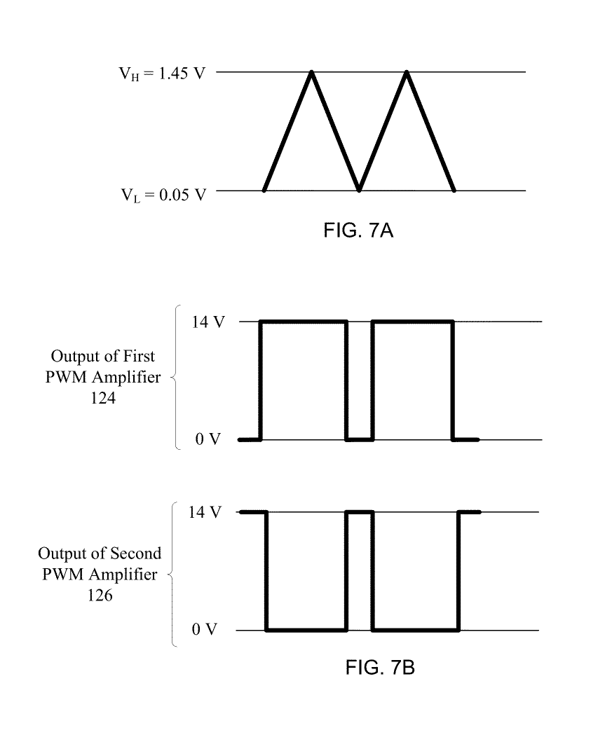

For example, FIG. 7A is a plot of a corresponding triangle wave signal produced by the oscillator circuit 122. FIG. 7B is a plot of the voltage output produced by the first PWM amplifier 124 and the second PWM amplifier 126 for the triangle wave signal of FIGS. 7A and Vᵢₙ=1.25 V. Because the output of PWM driver 120 corresponds to the difference between the average of the first PWM amplifier output and the average of the second PWM amplifier output, the total output voltage of the PWM driver 120 is 10 V and thus matches the voltage (and current) produced by the linear driver 110.

When the operating current of the VCM 200 changes, the error amplifier 140 automatically adjusts Vᵢₙ and thus changes the duty cycle of the pulse train signals produced by the amplifiers of PWM driver 120. For example, Table IV below shows the duty cycles for the first PWM amplifier 124 and for the second PWM amplifier 126 at different currents through the VCM 200 when V_{DD}=14 V.

TABLE IV

| | | | | | | | | |
|---|---|---|---|---|---|---|---|---|
| DUTY First | 100% | 92.9% | 85.7% | 78.6% | 71.4% | 64.3% | 57.1% | 50% |
| Amplifier 124 | | | | | | | | |
| DUTY Second | 0 | 7.1% | 14.3% | 21.4% | 28.6% | 35.7% | 42.9% | 50% |
| Amplifier 126 | | | | | | | | |
| Output of | 1.45 V | 1.35 V | 1.25 V | 1.15 V | 1.05 V | 0.95 V | 0.85 V | 0.75 V |
| Error Amp 140 | | | | | | | | |
| I_{OUT} | 1.4 A | 1.2 A | 1.0 A | 0.8 A | 0.6 A | 0.4 A | 0.2 A | 0 A |

A number of implementations have been described. Nevertheless, various modifications may be made without departing from the spirit and scope of the invention. Other implementations are within the scope of the claims.

What is claimed is:

1. A circuit device comprising:
a linear driver circuit;
a pulse-width modulation (PWM) driver circuit;
an oscillator circuit having an output coupled to the PWM circuit; and
a feed-forward circuit coupled to the oscillator circuit, the feed-forward circuit being configured to adjust an output of the oscillator circuit so that an output of the PWM circuit substantially matches an output of the linear driver circuit.

2. The circuit device of claim 1, wherein the feed-forward circuit is configured to adjust the output of the oscillator circuit so that the output of the PWM driver circuit matches the output of the linear driver circuit when a power source voltage deviates from a predetermined power source voltage.

3. The circuit device of claim 1, wherein the feed-forward circuit is configured to set both maximum and minimum amplitudes of an output of the oscillator circuit.

4. The circuit device of claim 3, wherein the feed-forward circuit is configured to set the maximum and minimum amplitudes based on a power source voltage.

5. The circuit device of claim 3, wherein the feed-forward circuit is configured to set a difference between the maximum and minimum amplitudes approximately equal to a ratio of a power source voltage to a gain of the linear driver circuit.

6. The circuit device of claim 1, wherein the feed-forward circuit comprises a plurality of operational amplifiers.

7. The circuit device of claim 1, wherein an output of a first operational amplifier of the feed-forward circuit is coupled to a positive input of a second operational amplifier of the feed-forward circuit and to a positive input of a third operational amplifier of the feed-forward circuit.

8. The circuit device of claim 7, wherein an output of the second operational amplifier of the feed-forward circuit is coupled to the oscillator circuit to set a maximum output voltage of the oscillator circuit.

9. The circuit device of claim 7, wherein an output of the third operational amplifier of the feed-forward circuit is coupled to the oscillator circuit to set a minimum output voltage of the oscillator circuit.

10. The circuit device of claim 1, further comprising a voice coil motor, wherein an output of each of the linear driver circuit and the PWM driver circuit is coupled to voice coil motor through a switch.

11. The circuit device of claim 10, further comprising an error detection circuit to detect a change in current in the voice coil motor, the error detection circuit being coupled to the PWM driver circuit and to the linear driver circuit.

12. The circuit device of claim 11, wherein the linear driver circuit comprises first and second linear amplifiers, the output of the error detection circuit being coupled to an input of each linear amplifier.

13. The circuit device of claim 11, wherein the PWM driver circuit comprises first and second operational amplifiers, the output of the error detection circuit being coupled to a positive input of the first operation amplifier and to a negative input of the second operation amplifier.

14. The circuit device of claim 13, wherein the output of the oscillator circuit is coupled to a negative input of the first operational amplifier and to a positive input of the second operational amplifier.

15. A method of adjusting a gain of a pulse-width modulation (PWM) driver circuit, the method comprising:
modifying, using feed-forward circuitry, an output of an oscillator circuit coupled to the PWM driver circuit so that the gain of the PWM driver circuit substantially matches a gain of a linear driver circuit.

16. The method of claim 15, wherein modifying the output of the oscillator circuit comprises changing maximum and minimum output amplitudes of the oscillator circuit.

17. The method of claim 16, wherein changing the maximum and minimum output amplitudes of the oscillator circuit is based on a power source voltage coupled to the feed-forward circuitry.

18. The method of claim 16, wherein modifying the output of the oscillator circuit comprises adjusting a difference between maximum and minimum output amplitudes of the oscillator circuit.

19. The method of claim 18, wherein adjusting the difference between the maximum and minimum output amplitudes comprises setting the difference equal to a ratio of a power source voltage to the gain of the linear driver circuit.

20. The method of claim 15, further comprising:
coupling the output of the oscillator circuit to a negative input of a first operational amplifier of the PWM driver circuit and to a positive input of a second operational amplifier of the PWM driver circuit; and
coupling an output of an error detection circuit to a positive input of the first operational amplifier and to a negative input of the second operational amplifier.

21. The method of claim 20, further comprising coupling the output of the error detection circuit to an input of the linear driver circuit.

22. A method of driving a voice coil motor, the method comprising:
driving the voice coil motor with a linear driver circuit over a first operating range;
driving the voice coil motor with a pulse width modulation (PWM) driver circuit over a second operating range; and
modifying, using feed-forward circuitry, an output of an oscillator circuit coupled to the PWM driver circuit so that a gain of the PWM driver circuit matches a gain of the linear driver circuit.

23. A hard disk drive comprising:
a voice coil motor;
a linear driver circuit;
a pulse-width modulation (PWM) driver circuit, wherein an output of each of the linear driver circuit and the PWM driver circuit is coupled to the voice coil motor through a switch;
an oscillator circuit having an output coupled to the PWM driver circuit; and
a feed-forward circuit coupled to the oscillator circuit, the feed-forward circuit being operable to adjust an output of the oscillator circuit so that a gain of the PWM driver circuit substantially matches a gain of the linear driver circuit.

24. A device comprising:
a linear driver circuit;
a pulse-width modulation (PWM) driver circuit;
an oscillator circuit having an output coupled to the PWM driver circuit; and
a feed-forward circuit coupled to the oscillator circuit, the feed-forward circuit being operable to adjust an output of the oscillator circuit so that output currents of the linear driver circuit and the pulse-width modulation driver circuit become the same when the same input voltages are provided to the linear driver circuit and the pulse-width modulation driver circuit.
